(19) United States
(12) Patent Application Publication
(10) Pub. No.: US 2012/0045591 A1
(43) Pub. Date: Feb. 23, 2012

(54) PLASMA PROCESSING APPARATUS, DEPOSITION METHOD, METHOD OF MANUFACTURING METAL PLATE HAVING DLC FILM, METHOD OF MANUFACTURING SEPARATOR, AND METHOD OF MANUFACTURING ARTICLE

(75) Inventor: Ge Xu, Hachioji-shi (JP)

(73) Assignee: CANON ANELVA CORPORATION, Kawasaki-shi (JP)

(21) Appl. No.: 13/195,291

(22) Filed: Aug. 1, 2011

(30) Foreign Application Priority Data
Aug. 19, 2010 (JP) 2010-183592
May 11, 2011 (JP) 2011-105944

(51) Int. Cl. C23C 16/50; C23C 16/26

(52) U.S. Cl. 427/577; 118/723 R; 427/569

(57) ABSTRACT

A plasma processing apparatus includes a holder holding an object to be processed in a vacuum chamber while being electrically connected to the object, a first take-up portion configured to take up an electrically conductive sheet and set at a potential different from that of the object at the time of plasma processing, and a second take-up portion configured to take up the electrically conductive sheet which is fed from the first take-up portion and passes through a position facing a processing surface of the object held by the holder.

### BACKGROUND OF THE INVENTION

1. Field of the Invention

The present invention relates to a plasma processing apparatus, a deposition method, a method of manufacturing a metal plate having DLC (Diamond Like Carbon) film, a method of manufacturing a separator, and a method of manufacturing an article and, more particularly, to a plasma processing apparatus suitable for the plasma processing of depositing an insulating film on an electrode, a deposition method, a method of manufacturing a metal plate having a DLC film by using such a plasma processing apparatus, a method of manufacturing a separator, and a method of manufacturing an article.

2. Description of the Related Art

A hard carbon film or DLC film is expected to be applied to protective coating for various types of mechanical and electronic components or functional devices owing to its properties (high hardness, high abrasion resistance, high lubricating ability, and high chemical resistance). As a method of forming this DLC film, plasma CVD is known, which forms a film by performing plasma decomposition of a hydrocarbon gas and depositing the ions on a substrate.

Out of such methods, a plasma CVD method for applying DC or pulsed DC power to a target member is a processing method using a target member as a cathode and a vacuum vessel or a shield surrounding the target member as an anode (see “SOKEIZAI”, issued by The SOKEIZAI Center, Vol. 48 (2007), December, pp. 15 to 20). This technique can form a DLC film on the surface of a target member by causing hydrocarbon gas ions generated by a plasma discharge between the target member and the shield to collide with the surface of the target member. DLC deposition by a DC or pulsed DC discharge is widely used as compared with deposition using an RF discharge because DLC deposition uses an inexpensive apparatus configuration and can easily cope with a target member having a large area and a complicated shape.

According to the conventional DLC deposition technique using a DC or pulsed DC discharge, however, a carbon film is also deposited on the anode, which is the vacuum chamber or the shield surrounding a target member, due to the decomposition of a hydrocarbon gas. The carbon film deposited on the anode has a large hydrogen content in the film and a high insulation property. Depositing an insulating film on the anode will gradually change the state of anode glow generated near the anode. This may lead to a failure to obtain reproducibility of discharge and deposition. In addition, since film deposition on the anode is not uniform, an anode glow may concentrate on a portion which keeps conductivity because of a small film deposition. This may cause frequent abnormal discharges.

Conventionally, for stable discharge and deposition, a shield as an anode on which an insulating film is deposited is periodically replaced by a new one. This method, however, requires to open the vacuum chamber to the atmosphere for replacing operation, and hence may prolong the maintenance time.

There is also available a method of removing a deposited film in a vacuum chamber by introducing an etching gas, for example, oxygen and causing a discharge when a carbon film is to be etched. However, the etching rate for a deposited film on the anode is low because of the absence of an ion assistance effect, and hence it takes time longer than that required for deposition to completely etch the deposited film.

In addition, Japanese Patent Laid-Open No. 2007-191754 discloses a technique for maintaining the stability of a long-time discharge by using a compact anode, heating the anode by extremely concentrating currents on the anode, and changing a deposited carbon film into a conductive film. However, the concentration of currents on the anode causes an uneven overall discharge. This makes it difficult to secure even deposition on an especially large substrate.

### SUMMARY OF THE INVENTION

The present invention is advantageous for obtaining high reproducibility in deposition processing by stabilizing plasma discharge conditions even in the long-time continuous operation of a plasma processing apparatus.

The first aspect of the present invention provides a plasma processing apparatus which includes a holder holding an object to be processed in a vacuum chamber while being electrically connected to the object, the apparatus comprising a first take-up portion configured to take up an electrically conductive sheet and set at a potential different from that of the object at the time of plasma processing, and a second take-up portion configured to take up the electrically conductive sheet which is fed from the first take-up portion and passes through a position facing a processing surface of the object held by the holder.

The second aspects of the present invention provides a deposition method of forming a carbon film coating on a surface of a metal plate by using the above plasma processing apparatus, the method comprising a step of causing the second take-up portion to take up a portion of a surface of the electrically conductive sheet, on which an insulating film is deposited, and to position a portion of the surface of the electrically conductive sheet, on which insulating film is not deposited, so as to face a processing surface of the object held by the holder.

The third aspect of the present invention provides a method of manufacturing a metal plate having a DLC (Diamond Like Carbon) film, which includes a process of forming a carbon film coating on a surface of a metal plate by using the above plasma processing apparatus, the method comprising a step of causing the second take-up portion to take up a portion of a surface of the electrically conductive sheet, on which an insulating film is deposited, and to position a portion of the surface of the electrically conductive sheet, on which insulating film is not deposited, so as to face a processing surface of the object held by the holder.

The fourth aspect of the present invention provides a method of manufacturing a separator which includes a process of forming a carbon film coating on a surface of a predetermined metal plate by using the above plasma processing apparatus, the method comprising a step of causing the second take-up portion to take up a portion of a surface of the electrically conductive sheet, on which an insulating film is deposited, and to position a portion of the surface of the electrically conductive sheet, on which insulating film is not deposited, so as to face a processing surface of the object held by the holder.

The fifth aspect of the present invention provides a plasma processing apparatus for performing plasma processing on an object to be processed in a vacuum vessel, the apparatus comprising a support mechanism configured to support an electrically conductive sheet so as to make a part of the electrically conductive sheet face the object, the electrically conductive sheet extending between a first roller and a second roller such that the second roller takes up the electrically conductive sheet from the first roller, wherein plasma processing is performed for the object while a voltage is applied between the electrically conductive sheet and the object.

The sixth aspect of the present invention provides a method of manufacturing an article, the method comprising a step of performing plasma processing for an object while applying a voltage between an electrically conductive sheet and an object to be processed in a state in which a first portion of the electrically conductive sheet faces the object, the electrically conductive sheet extending between the first roller and the second roller such that the second roller takes up the electrically conductive sheet from the first roller, and a step of causing the second roller to take up the electrically conductive sheet so as to move the first portion.

One of the aspects of the present invention is advantageous in that stable deposition is implemented for a long period of time by taking up an electrically conductive sheet (metal sheet) covered with an insulating film to feed a new metal surface so as to prevent a change in discharge or abnormal discharge due to the deposition of an insulating film on an electrode.

In addition, according to one aspect of the present invention, since there is no need to clean a deposited film from a shield, it is possible to greatly improve the utilization efficiency and productivity of the apparatus. This leads to a reduction in production cost.

Further features of the present invention will become apparent from the following description of exemplary embodiments with reference to the attached drawings.

### BRIEF DESCRIPTION OF THE DRAWINGS

FIG. 1 is a side view of a deposition apparatus according to the first embodiment of the present invention;

FIG. 2 is a sectional view of the deposition apparatus according to the first embodiment of the present invention;

FIG. 3 is a sectional view of a deposition apparatus according to the second embodiment of the present invention;

FIG. 4 is a sectional view of a deposition apparatus according to the third embodiment of the present invention; and

FIG. 5 is a graph showing a comparative table between the deposition rates and the etching rates on a cathode and an anode in an example.

### DESCRIPTION OF THE EMBODIMENTS

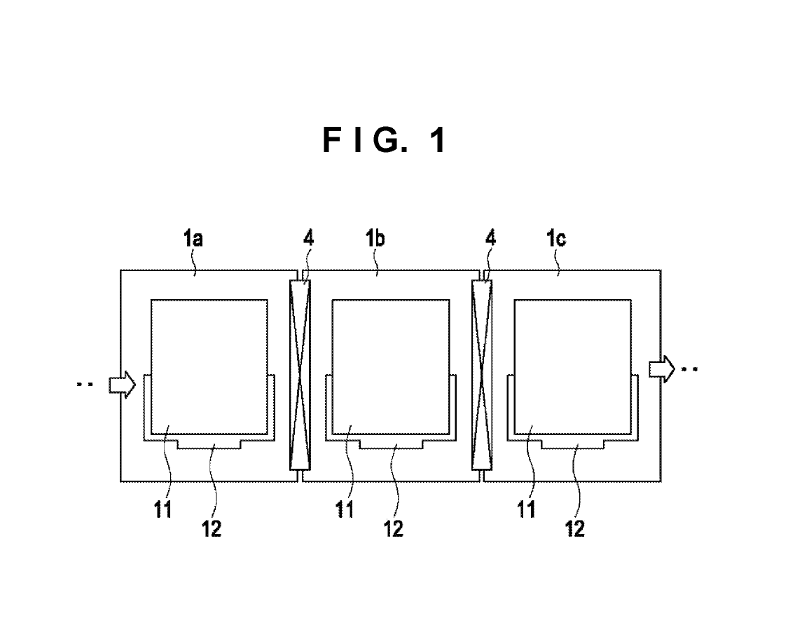

FIG. 1 is a schematic view of a vacuum processing apparatus according to the first embodiment of the present invention. The vacuum processing apparatus (plasma processing apparatus) in FIG. 1 is an inline type vacuum processing apparatus which includes a plurality of vacuum chambers (vacuum vessels) 1a, 1b, and 1c coupled to each other, and sequentially processes an object to be processed in the plurality of vacuum chambers 1a, 1b, and 1c. Each of the vacuum chambers 1a, 1b, and 1c is evacuated by an evacuation system (not shown). A gate valve 4 is provided for each vacuum chamber to allow to independently perform specific vacuum processing. The vacuum chambers 1a, 1b, and 1c respectively include transport devices for sequentially transporting an object 11 to be processed (a target member or metal plate). The transport devices transport a holder 12, on which an object to be processed is placed, along a transport route provided in the plurality of vacuum chambers 1a, 1b, and 1c so as to extend through them.

The vacuum processing apparatus or plasma processing apparatus according to the present invention can be formed by coupling a plurality of vacuum chambers each of which can perform an arbitrary vacuum process. The vacuum processing apparatus or plasma processing apparatus exemplified in FIG. 1 includes the vacuum chamber 1a for heating, the vacuum chamber 1b for plasma processing (deposition processing) by plasma CVD, and the vacuum chamber 1c as a cooling unit. The vacuum chamber 1a (heating unit) heats an object to be processed to a predetermined temperature. The vacuum chamber 1b (discharge unit) performs deposition processing by plasma CVD. The vacuum chamber 1c (cooling unit) cools a substrate to a predetermined temperature. In the following description, the vacuum chambers 1a, 1b, and 1c each will be referred to as a “vacuum chamber 1” hereinafter if there is no need to distinguish them.

After the processing of the object 11 in each vacuum chamber 1 is complete, the gate valve 4 is opened to transport the object 11 as a target member placed on the holder 12 to the next vacuum chamber 1. After the transport is complete, the gate valve 4 is closed, and each vacuum chamber 1 repeats similar processing for the next object 11. Although FIG. 1 shows three vacuum chambers, the number of vacuum chambers to be coupled is arbitrary.

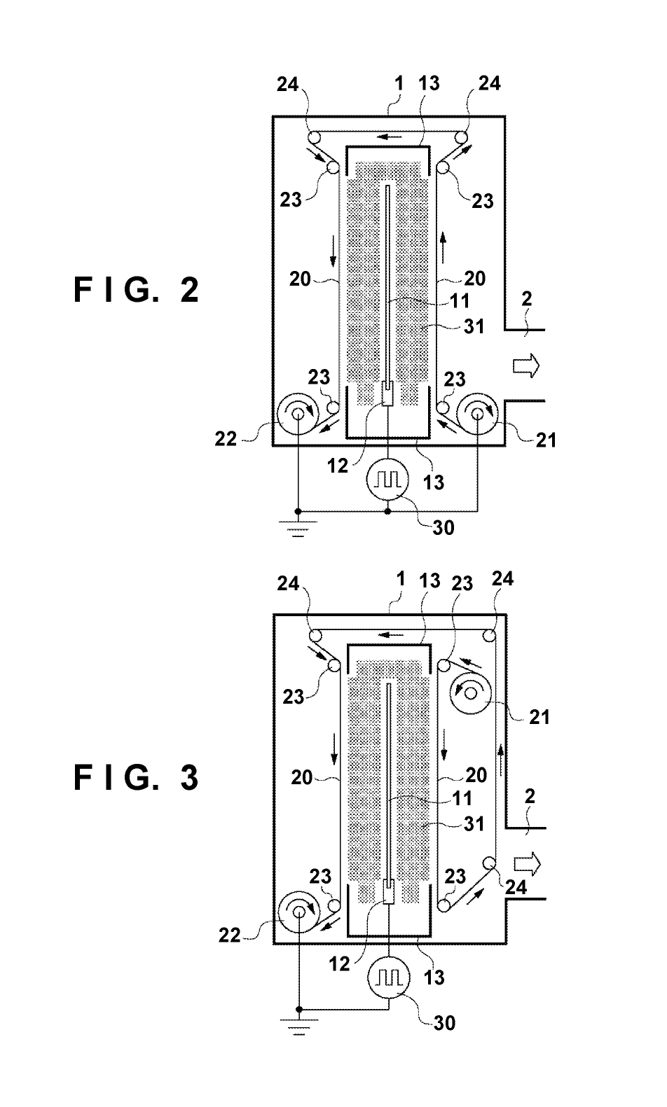

FIG. 2 is a sectional view of the vacuum chamber 1 in the vacuum processing apparatus shown in FIG. 1 taken across the transport path. The vacuum processing apparatus in FIG. 2 is configured to simultaneously form films on the two surfaces of the object 11. Obviously, however, this apparatus can be applied to the processing of forming a film on one surface. A deposition gas is introduced into the vacuum chamber (vacuum vessel) 1, and the pressure in the vacuum chamber 1 is set to a predetermined pressure by controlling a gas flow rate and the conductance of an exhaust port 2. After the pressure in the vacuum chamber 1 reaches the predetermined pressure, DC or pulsed DC power 30 is applied to the holder 12 as a cathode and the object 11. This processing generates a plasma 31 between the object 11 and a grounded metal sheet 20 (electrically conductive sheet) as an anode. The plasma decomposes the deposition gas, and ions accelerated by the potential of the cathode form a film on the surface of the object 11. Note that since the holder 12 is configured to be electrically connected to the object 11 while holding it, it is possible to apply the DC or pulsed DC power 30 to the object 11 through the holder 12.

The metal sheet 20 is wound around a roller 21. A roller 22 takes up the metal sheet 20 fed from the roller 21 through a position facing the processing surface of the object 11. First of all, the entire unused metal sheet is wound around the roller 21 (first take-up portion). With the progress of continuous deposition processing of the object 11, the deposition of an insulating film on the surface of the metal sheet 20 progresses, resulting in an increase in electric resistance. For example, the following operation is performed to prevent an increase in electric resistance on the surface of the metal sheet 20 from influencing the stability of discharge. After the completion of deposition on a predetermined number of objects 11, the roller 22 (second take-up portion) is rotated to take up a portion of the metal sheet 20, on which an insulating film is deposited, thereby feeding metal sheet 20 from the roller 21 and making an unused portion (that is, a new metal surface) face the discharge space. This can reduce the surface resistance of the metal sheet 20 as an anode again, and hence can secure the stability of discharge.

The rollers 21 and 22 may be configured to incorporate refrigerant flow paths through which cooling water (refrigerant) flows. Cooling the rollers 21 and 22 can suppress a rise in the temperature of the metal sheet 20. More specifically, a flow path through which a refrigerant flows is preferably formed in the core portion of at least one of the roller 21 and the roller 22.

Although no limitation is imposed on the metal sheet 20 in terms of material and thickness, a thin aluminum plate having a thickness of as thin as 0.1 mm or less, for example, 0.01 mm to 0.05 mm is preferably used in consideration of cost and storage property. Guide rollers 23 (regulating portions) are provided between the rollers 21 and 22 and the object 11. Positioning the guide rollers 23 can regulate the distance between the metal sheet 20 and the object 11, that is, the distance between the discharge anode and the discharge cathode. This makes it possible to keep the distance constant regardless of how the metal sheet 20 is wound around the rollers 21 and 22. The guide rollers 23 also serve to adjust the tensile force of the metal sheet 20. More specifically, the guide rollers 23 may be attached slidably through elastic members such as springs to press the metal sheet 20 with constant loads. Obviously, it is possible to adjust the tensile force of the metal sheet 20 by keeping applying tension to one or both of the rollers 21 and 22. The guide rollers 23 constitute a support mechanism for supporting the electrically conductive sheet 20, which is stretched or extending between the rollers 21 and 22 so as to be taken up by them, so as to make a portion between the rollers 21 and 22 face the object 11.

A shield 13 surrounding a discharge space to prevent film attachment can be mounted on the wall of the vacuum chamber 1. The shield 13 is provided with openings to make one of the two surfaces of the metal sheet 20 face the first and second processing surfaces of the object 11. Since the shield 13 is set at a floating potential, even an increase in film deposition on the shield 13 due to continuous processing has no influence on discharge. Typically, the shield 13 can be constituted by a plurality of parts.

As the deposition of a film on the metal sheet 20 as an anode progresses, the rollers 21 and 22 are properly rotated to make one roller 22 take up a portion of the metal sheet 20, on which the film is deposited while making the other roller 21 feed the metal sheet 20, thereby making a new portion of the metal sheet 20 face the object 11 as a cathode. More specifically, in this embodiment, since one of the two surfaces of the metal sheet 20 is used, it is preferable to take up a portion, of the metal sheet 20, which is stretched between the rollers 21 and 22 when taking up a portion of the metal sheet 20 on which the film is deposited.

When the metal sheet 20 wound around the roller 21 is used up, the rollers 21 and 22 can be simultaneously replaced. More specifically, it is possible to replace the roller 22 which has taken up the metal sheet 20 on which the film is deposited with a new one, and to replace the roller 21 from which the metal sheet 20 has been used up with a roller 21 around which a new metal sheet is wound.

FIG. 3 is a sectional view of a vacuum processing apparatus according to the second embodiment of the present invention. A major difference from the first embodiment in FIG. 2 is that one of the two surfaces of a metal sheet 20 faces one of the two surfaces (upper and lower surfaces) of an object 11 as a cathode, and the other of the two surfaces of the metal sheet 20 faces the other of the two surfaces (upper and lower surfaces) of the object 11. More specifically, the second embodiment differs in arrangement from that first embodiment in that the position of a roller 21 around which the unused metal sheet 20 is wound is changed, and guide rollers 24 are added.

In the second embodiment, since the two surfaces (upper and lower surfaces) of a metal sheet are used, the method of taking up a portion, of the metal sheet, on which a film is deposited, and replacing the portion with a new portion of the metal sheet differs from the method in the first embodiment described above. That is, the metal sheet 20 may be moved to replace a portion, of the metal sheet in the region extending between the upper and lower pairs of rollers 23, on which a film is formed by an amount exceeding an allowable amount due to exposure to a plasma with a portion on which no film is formed or the amount of a film formed is smaller than the allowable value and make it face the object 11. For example, it is possible to replace a portion of the metal sheet 20 which is exposed to a plasma with a new portion by feeding the metal sheet from the roller 21 by a length corresponding to the distance between one pair of guide rollers 23 which are placed in the vertical direction to support the metal sheet 20 so as to face a surface (the first or second processing surface) of the object. This reduces the amount of the metal sheet 20 used as compared with the first embodiment. For example, the amount of metal sheet used becomes equal to or less than the half of the amount in the first embodiment. This allows to expect an increase in continuous operation time and a reduction in the amount of metal sheet used.

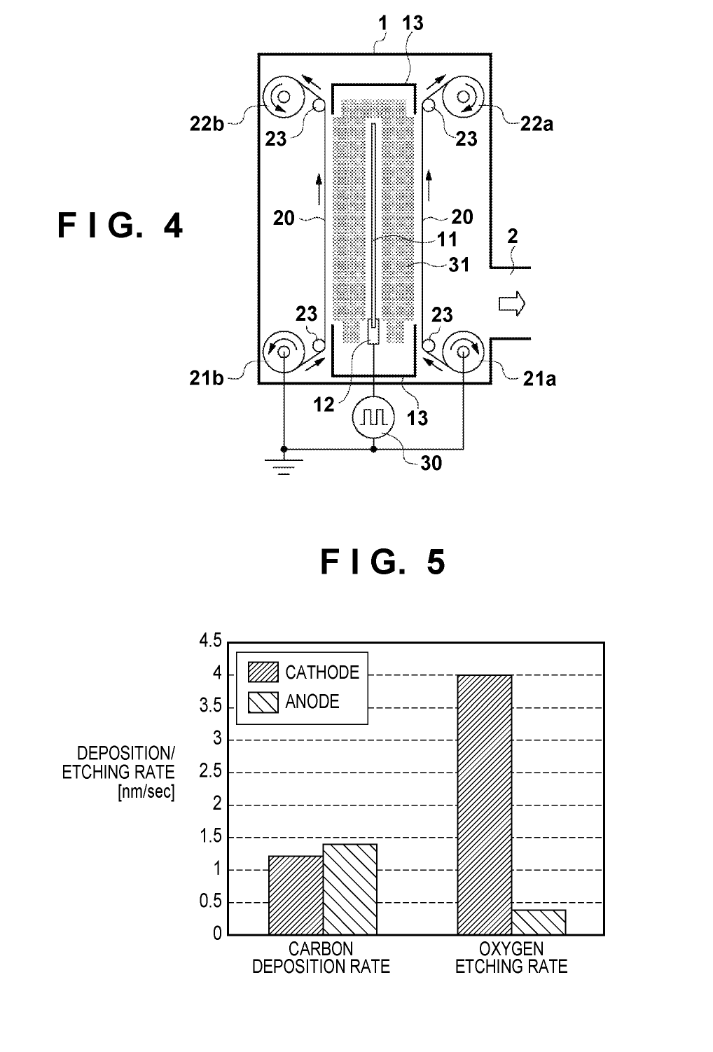

FIG. 4 is a cross-sectional view of a vacuum processing apparatus according to the third embodiment of the present invention. A main difference from the first embodiment in FIG. 2 is that the third embodiment includes two sets of rollers 21 and 22, which are respectively placed on the two sides of an object 11 as a cathode. As shown in FIG. 4, the roller set around which a metal sheet 20 stretched on one side of the object 11 is wound includes rollers 21a and 22a, and the roller set which takes up the metal sheet 20 stretched on the other side of the object 11 includes rollers 21b and 22b.

The rollers 22a and 22b are coupled so as to be driven in synchronism with the driving shaft of one motor. In the arrangement in FIG. 4, the rollers 22a and 22b are arranged on the upper side, and the rollers 21a and 21b are arranged on the lower side. However, the positions of these rollers may be reversed vertically. This embodiment can simplify the apparatus arrangement because the distance over which a metal sheet is stretched is short. In addition, providing the two sets of rollers 21 and 22 can increase the amount of metal sheet placed at once in a vacuum chamber and prolong the time during which continuous operation can be performed.

In each embodiment described above, one of the processing chambers constituting the inline type vacuum processing apparatus is provided with the rollers 21 and 22 and the guide rollers 23 between which a metal sheet according to the present invention is stretched. However, the present invention is not limited to the inline type vacuum processing apparatus. Obviously, for example, the present invention can be applied to a plasma CVD processing chamber configured for batch processing.

### Example

A plurality of 200-mm square, 0.1-mm thick stainless steel plates (metal plates) are respectively held as the objects 11 on aluminum substrate holders in the vertical direction, and are processed by a plurality of vacuum chambers 1. In a CVD processing chamber as one of these chambers, pulsed DC power is applied to the object to coat it with a carbon film by plasma CVD using a hydrocarbon gas, for example, ethylene gas. The 0.05-mm thick aluminum sheet 20 is stretched as an anode (ground potential) to face the two surface of the object 11. As a means for increasing the plasma density by confining a discharge, a magnet array (magnet) constituted by a plurality of permanent magnets can be placed behind (on the side opposite to the object) the aluminum sheet 20 as an anode. The distance between the aluminum sheet as an anode and the object 11 as a cathode is kept constant at 60 mm. Obviously, it is possible to use an electromagnet as a magnet array to be placed behind the metal sheet 20.

As deposition conditions, the flow rate of ethylene gas to be introduced was adjusted to 100 sccm, and the internal pressure of the camber was adjusted to 4 Pa. A −400-V, 150-kHz pulsed DC power was applied to the object and the holder to perform a discharge for 30 sec to form a carbon film. Film thickness measurement using a step difference meter revealed that the deposition rates on the stainless steel plate as a cathode and the central portion of the aluminum sheet as an anode were 1.2 nm/sec and 1.4 nm/sec, respectively. The deposition rate on the cathode is slightly lower than that on the anode due to ion bombardment and the resultant temperature rise.

In addition, a discharge was performed for 15 sec by applying a −300-V, 150-kHz pulsed DC power to the cathode at 500 sccm of oxygen gas and a pressure of 7 Pa. The etching rates of carbon films deposited on the cathode and the anode were then evaluated. Measurement using a step difference meter revealed that the etching rates on the stainless steel plate as a cathode and the central portion of the aluminum sheet as an anode were 4.0 nm/sec and 0.4 nm/sec, respectively. Owing to the assist effect of ion bombardment, the etching rate on the cathode is about 10 times higher than that on the anode.

FIG. 5 shows the above measurement results. The results show that the carbon deposition rate on the anode is three times or more higher than the etching rate obtained by oxygen discharge. When cleaning an anode by oxygen discharge etching using a dummy substrate as a cathode, it requires a processing time three times longer than the deposition time, and the productivity of the apparatus decreases to ¼ or less of that in continuous deposition processing without cleaning. It may be conceivable to increase the etching rate by increasing the power to be applied to the cathode. However, large power has already been applied to the cathode, and hence performing a discharge with a higher voltage and a large current may cause an abnormal discharge or damage the holder. Using the metal sheet wound around the rollers as an anode allows to perform continuous deposition processing without cleaning and can maintain high productivity.

The above embodiment and example have exemplified the case in which a DLC film is formed on the surface of the object 11. Obviously, however, the present invention can be applied to the plasma processing (deposition processing) of forming an insulating film on the cathode by using TiN, TiCn, TiAlN, TiAlCN, TiAlON, TiAlSiCNO, or the like. The above embodiments have exemplified the plasma CVD deposition processing using an object as a cathode and the metal sheet 20 as an anode. Obviously, however, the present invention can also be applied to a plasma etching apparatus using an object as an anode and the metal sheet 20 as a cathode.

Application examples of the above embodiments and example include the manufacture of a separator used for a polymer electrolyte fuel cell (PEFC) by using the plasma processing apparatus and deposition method according to the present invention. The plasma processing apparatus and deposition method according to the present invention can be applied to the process of forming a carbon film coating on the surface of a stainless steel plate having a predetermined shape. More specifically, a 200-mm square, 0.1-mm thick stainless steel plate is vertically held by an aluminum substrate holder and transported to a plurality of vacuum chambers. In a CVD processing chamber as one of these chambers, pulsed DC power is applied to the object to coat it with a carbon film by plasma CVD using ethylene gas.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefits of Japanese Patent Application Nos. 2010-183592 and 2011-105944, filed Aug. 19, 2010 and May 11, 2011, respectively which are hereby incorporated by reference herein in their entirety.

What is claimed is:

1. A plasma processing apparatus which includes a holder holding an object to be processed in a vacuum chamber while being electrically connected to the object, the apparatus comprising:
a first take-up portion configured to take up an electrically conductive sheet and set at a potential different from that of the object at the time of plasma processing; and
a second take-up portion configured to take up the electrically conductive sheet which is fed from the first take-up portion and passes through a position facing a processing surface of the object held by the holder.

2. The apparatus according to claim 1, further comprising a regulating portion that is placed in contact with a portion, of the electrically conductive sheet, which is located between the first take-up portion and the second take-up portion and configured to regulate a distance between the portion and the object.

3. The apparatus according to claim 1, wherein portions of the electrically conductive sheet, which are located between the first take-up portion and the second take-up portion are placed on both sides of front and back surfaces of the object held by the holder.

4. The apparatus according to claim 3, wherein the portions of the electrically conductive sheet, which are located between the first take-up portion and the second take-up portion are positioned to make one of two surfaces of the electrically conductive sheet face both of two surfaces of the object held by the holder.

5. The apparatus according to claim 3, wherein the portions of the electrically conductive sheet, which are located between the first take-up portion and the second take-up portion are positioned to make one of two surfaces of the electrically conductive sheet face one of two surfaces of the object held by the holder and to make the other of the two surfaces of the electrically conductive sheet face the other of the two surfaces of the object held by the holder.

6. The apparatus according to claim 1, wherein a refrigerant flow path through which a refrigerant flows is provided for at least one of the first take-up portion and the second take-up portion.

7. The apparatus according to claim 1, further comprising a magnet which is arranged such that a portion of the electrically conductive sheet, which faces the object held by the holder is sandwiched by the magnet and the object.

8. A deposition method of forming a carbon film coating on a surface of a metal plate by using a plasma processing apparatus defined in claim 1, the method comprising a step of causing the second take-up portion to take up a portion of a surface of the electrically conductive sheet, on which an insulating film is deposited, and to position a portion of the surface of the electrically conductive sheet, on which insulating film is not deposited, so as to face a processing surface of the object held by the holder.

9. A method of manufacturing a metal plate having a DLC (Diamond Like Carbon) film, which includes a process of forming a carbon film coating on a surface of a metal plate by using a plasma processing apparatus defined in claim 1, the method comprising a step of causing the second take-up portion to take up a portion of a surface of the electrically conductive sheet, on which an insulating film is deposited, and to position a portion of the surface of the electrically conductive sheet, on which insulating film is not deposited, so as to face a processing surface of the object held by the holder.

10. A method of manufacturing a separator which includes a process of forming a carbon film coating on a surface of a predetermined metal plate by using a plasma processing apparatus defined in claim 1, the method comprising a step of causing the second take-up portion to take up a portion of a surface of the electrically conductive sheet, on which an insulating film is deposited, and to position a portion of the surface of the electrically conductive sheet, on which insulating film is not deposited, so as to face a processing surface of the object held by the holder.

11. A plasma processing apparatus for performing plasma processing on an object to be processed in a vacuum vessel, the apparatus comprising a support mechanism configured to support an electrically conductive sheet so as to make a part of the electrically conductive sheet face the object, the electrically conductive sheet extending between a first roller and a second roller such that the second roller takes up the electrically conductive sheet from the first roller,
wherein plasma processing is performed for the object while a voltage is applied between the electrically conductive sheet and the object.

12. A method of manufacturing an article, the method comprising:
a step of performing plasma processing for an object while applying a voltage between an electrically conductive sheet and an object to be processed in a state in which a first portion of the electrically conductive sheet faces the object, the electrically conductive sheet extending between the first roller and the second roller such that the second roller takes up the electrically conductive sheet from the first roller; and
a step of causing the second roller to take up the electrically conductive sheet so as to move the first portion.
